(19) United States
(12) Patent Application Publication
(10) Pub. No.: US 2022/0333911 A1
(43) Pub. Date: Oct. 20, 2022

(54) DISTANCE SENSING APPARATUS

(71) Applicant: Egis Technology Inc., Hsinchu City (TW)

(72) Inventor: Chen-Chih Fan, Hsinchu City (TW)

(73) Assignee: Egis Technology Inc., Hsinchu City (TW)

(21) Appl. No.: 17/715,965

(22) Filed: Apr. 8, 2022

Related U.S. Application Data
(60) Provisional application No. 63/176,896, filed on Apr. 20, 2021.

(30) Foreign Application Priority Data
Mar. 8, 2022 (TW) 111108354

(51) Int. Cl. G01B 11/02; G01B 9/02017

(52) U.S. Cl. CPC G01B 11/026; G01B 9/02017

(57) ABSTRACT

A distance sensing apparatus including a substrate, a light source, a sensing device and an encapsulation structure is provided. The sensing device includes a sensing element and a light-shielding structure. The light source disposed in a light source region emits a beam for irradiating an object to be sensed. The light-shielding structure is disposed on the sensing element. The light source and the sensing device are disposed in the encapsulation structure. The encapsulation structure has a first opening corresponding to a sensing region. The light-shielding structure is disposed between the sensing element and the first opening, and the sensing element receives a beam to be sensed reflected by the object to be sensed and penetrating the first opening and at least a light-transmitting hole of the light-shielding structure. The light source region and the sensing regions are interconnected in the encapsulation structure.

### CROSS-REFERENCE TO RELATED APPLICATION

This application claims the priority benefit of U.S. provisional application Ser. No. 63/176,896, filed on Apr. 20, 2021, and Taiwan application serial no. 111108354, filed on Mar. 8, 2022. The entirety of each of the above-mentioned patent applications is hereby incorporated by reference herein and made a part of this specification.

### BACKGROUND

### Technology Field

The disclosure relates to a distance sensing apparatus.

### Description of Related Art

With the development of optoelectronic technology, various photoelectric sensors have been developed, including LiDAR sensors, time-of-flight ranging sensors, or image sensors. Referring to FIG. 1, a conventional time-of-flight ranging sensor 100A includes an encapsulation structure 104, a light source 102, and a sensing element 111. An opening H1 corresponds to the sensing element 111, and an opening H2 corresponds to the light source 102. The light source 102 emits a beam 102L to irradiate an object to be sensed, and the sensing element 111 receives the beam reflected from the object to be sensed to determine the distance of the object to be sensed.

The width and position of the opening H1 may affect the sensing accuracy, so the opening H1 is required to be aligned with the sensing element 111. In addition, a blocking wall 103 is required to be configured in the encapsulation structure 104 to prevent a beam 1021 (an internal beam) emitted by the light source 102 from being transmitted to the sensing element 111 in the encapsulation structure 104, resulting in interference and degradation of product performance.

### SUMMARY

The disclosure provides a distance sensing apparatus, which prevents sensing accuracy from being affected by an opening of an encapsulation structure in a sensing region without configuring a blocking wall in the encapsulation structure.

According to an embodiment of the disclosure, a distance sensing apparatus including a substrate, a light source, a sensing device, and an encapsulation structure is provided. The sensing device includes a sensing element and a light-shielding structure. The light source is disposed in a light source region on the substrate and configured to emit a beam and irradiate an object to be sensed. The sensing device is disposed in a sensing region on the substrate. The light-shielding structure is disposed on the sensing element. The light source and the sensing device are disposed in the encapsulation structure. The encapsulation structure has a first opening corresponding to the sensing region. The light-shielding structure is disposed between the sensing element and the first opening, and the sensing element receives a beam to be sensed reflected from the object to be sensed through the first opening and at least one light-transmitting hole of the light-shielding structure. The light source region is connected to the sensing region in the encapsulation structure.

According to an embodiment of the disclosure, a distance sensing apparatus including a substrate, a light source, a sensing device, and an encapsulation structure is provided. The sensing device includes a sensing element and a microlens layer. The light source is disposed in a light source region on the substrate and configured to emit a beam and irradiate an object to be sensed. The sensing device is disposed in a sensing region on the substrate. The sensing element includes at least one sensing pixel. The microlens layer includes at least one microlens. The at least one microlens is disposed on the sensing element, and a vertical projection of a geometric center of the at least one microlens on the substrate is overlapped with a vertical projection of a geometrical center of the at least one sensing pixel on the substrate. A beam to be sensed reflected from the object to be sensed penetrates the at least one microlens and then is incident to the at least one sensing pixel. The light source and the sensing device are disposed in the encapsulation structure. The encapsulation structure has a first opening corresponding to the sensing region, the first opening is disposed corresponding to the at least one microlens, and a width of the first opening is greater than a field of view of the at least one microlens. The light source region is connected to the sensing region in the encapsulation structure.

In summary, the distance sensing apparatus provided by the embodiments of the disclosure includes a light-shielding structure or a microlens. The light-shielding structure or the microlens is used to limit the incident angle of a beam to be sensed which is transmitted to a sensing element to prevent the beam emitted by the light source from being transmitted inside the encapsulation structure and affecting the sensing accuracy. With the distance sensing apparatus provided by the embodiments of the disclosure, the sensing accuracy is prevented from being affected by the opening of the encapsulation structure in the sensing region without configuring a blocking wall in the encapsulation structure.

In order to make the features and advantages of the disclosure comprehensible, embodiments accompanied with drawings are described in detail below.

### BRIEF DESCRIPTION OF THE DRAWING

FIG. 1 is a schematic view of a time-of-flight ranging sensor according to a comparative example.

FIG. 2A is a schematic view of a distance sensing apparatus according to an embodiment of the disclosure.

FIG. 2B is a schematic view of a sensing region of the distance sensing apparatus of FIG. 2A.

FIG. 3 is a schematic view of a sensing device according to an embodiment of the disclosure.

FIG. 4 is a schematic view of a sensing region according to an embodiment of the disclosure.

### DESCRIPTION OF THE EMBODIMENTS

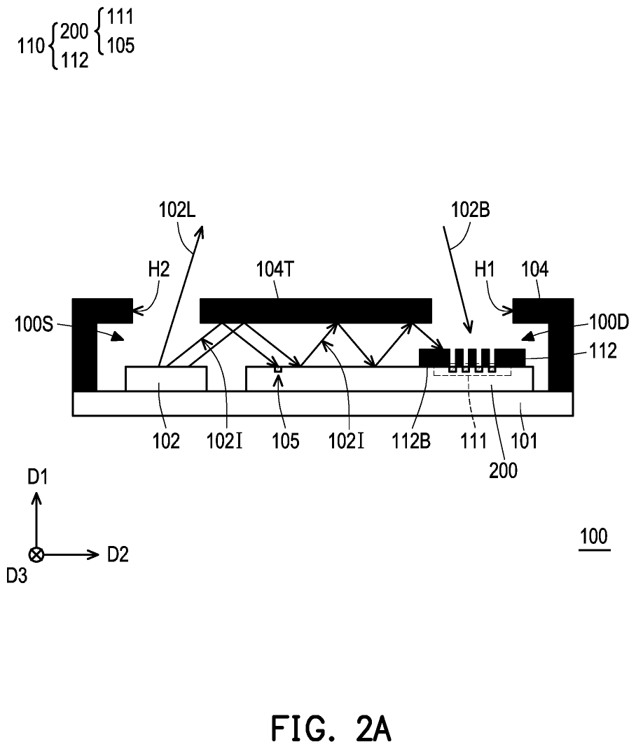

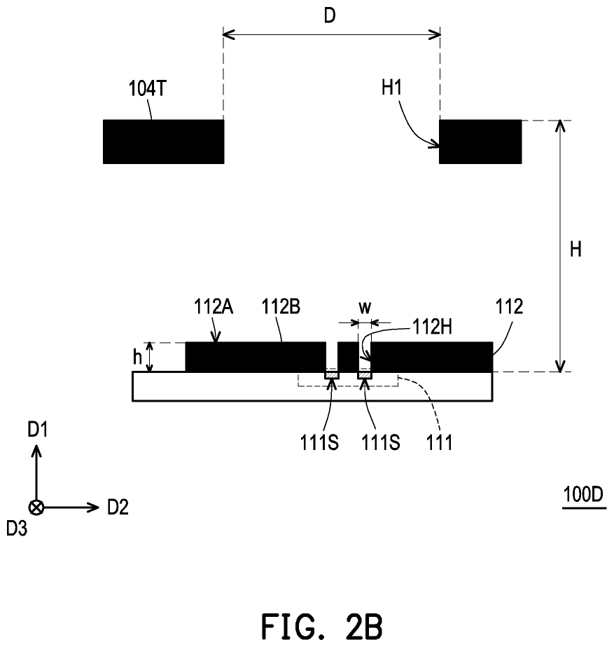

Referring to FIG. 2A and FIG. 2B, FIG. 2A is a schematic view of a distance sensing apparatus according to an embodiment of the disclosure, and FIG. 2B is a schematic view of a sensing region of the distance sensing apparatus of FIG. 2A. A distance sensing apparatus 100 includes a substrate 101, the light source 102, a light receiver 200, a sensing device 110, and the encapsulation structure 104. The light source 102 and the sensing device 110 are disposed in the encapsulation structure 104. The sensing device 110 includes the light receiver 200 and a light-shielding structure 112. The light receiver 200 is disposed on the substrate 101 and includes the sensing element 111, and the sensing element 111 is disposed on an upper surface of the light receiver 200 away from the substrate 101. The light source 102 is disposed in a light source region 100S on the substrate 101 to emit the beam 102L and irradiate a object to be sensed. The sensing device 110 is disposed in a sensing region 100D on the substrate 101, and the normal line of the substrate 101 is parallel to a first direction D1.

The light-shielding structure 112 is disposed on the sensing element 111. The sensing element 111 has multiple sensing pixels 111S disposed in an array on a plane formed by a second direction D2 and a third direction D3, and the light-shielding structure 112 has the sensing pixels 111S corresponding to multiple light-transmitting holes 112H.

The encapsulation structure 104 has the opening H1 corresponding to the sensing region 100D. The sensing element 111 corresponds to the opening H1. The light-shielding structure 112 is disposed between the sensing element 111 and the opening H1, and the sensing element 111 receives a beam 102B to be sensed reflected from the object to be sensed and passing through the opening H1 and the light-transmitting hole 112H of the light-shielding structure 112.

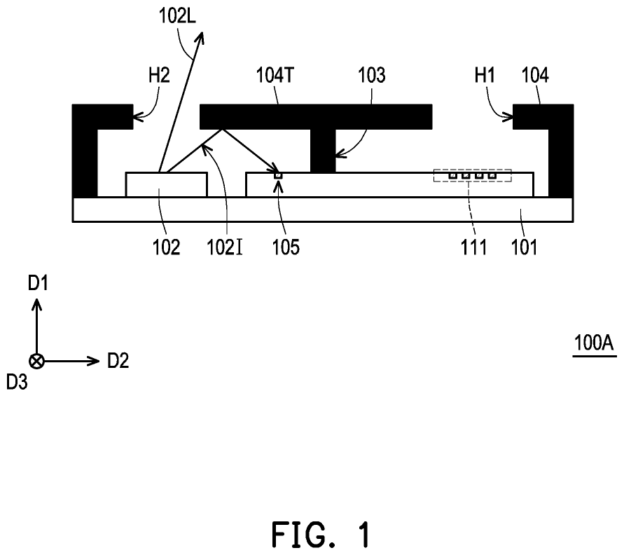

Compared with the comparative example shown in FIG. 1 in which the sensing accuracy of the time-of-flight ranging sensor 100A is ensured by controlling the width and position of the opening H1, the distance sensing apparatus 100 of the embodiment has the light-shielding structure 112 disposed on the sensing element 111, and the light-shielding structure 112 limits the range of the incident angle of the beam 102B to be sensed incident to the sensing element 111. Compared with the opening H1 being formed by assembly, the light-shielding structure 112 is directly formed by the semiconductor process, so the alignment between the light-shielding structure 112 and the sensing element 111 is easier and more precise than the alignment between the opening H1 and the sensing element 111. In other words, since the distance sensing apparatus provided in the embodiment uses the light-shielding structure 112 to limit the range of the incident angle of the beam 102B to be sensed incident to the sensing element 111, the sensing accuracy is prevented from being affected by the width and position of the opening H1.

In addition, also referring to FIG. 2A, the light source 102 may further emit the beam 1021, and the beam 1021 may be transmitted within the encapsulation structure 104. Specifically, the encapsulation structure 104 includes the opening H2 corresponding to the light source region 100S and a light shielding plate 104T between the opening H1 and the opening H2. The beam 1021 emitted by the light source 102 can be reflected on the light shielding plate 104T as shown in FIG. 2A and transmitted to the sensing element 111. Compared with the comparative example shown in FIG. 1, the blocking wall 103 is disposed to prevent the beam 1021 from being transmitted to the sensing element 111, and a light blocking wall 112B can also be disposed between the light-transmitting hole 112H and the light source 102 in the light-shielding structure 112 of the embodiment to block (absorb) the beam 1021, so that the beam 1021 is prevented from being transmitted to the sensing element 111 without configuring the blocking wall 103. In other words, in the embodiment, the light source region 100S is connected to the sensing region 100D in the encapsulation structure 104.

In an embodiment of the disclosure, referring to FIG. 2B, a width D of the opening H1 is greater than 2H×w/h−w. H is the distance between the opening H1 and the sensing element 111 in the first direction D1, h is the distance between a top surface 112A of the light-shielding structure 112 away from the sensing element 111 and the sensing element 111 in the first direction D1, w is the maximum width of the light-transmitting hole 112H in the second direction D2, the first direction D1 is parallel to the normal direction of the substrate 101, and the second direction D2 is perpendicular to the first direction D1. In such a case, even if the beam 1021 emitted by the light source 102 is reflected on the light shielding plate 104T and transmitted to the sensing region 100D, the beam 1021 may not be incident to the light-transmitting hole 112H. Since the beam 1021 is not incident to the sensing pixels 111S of the sensing element 111, the sensing result of the distance sensing apparatus 100 may not be interfered by the beam 1021. In an embodiment of the disclosure, the width D of the opening H1 is greater than 2H×w/h, so that the product performance may not be degraded resulting from assembly errors.

Referring to FIG. 2A again, in an embodiment of the disclosure, the light receiver 200 of the distance sensing apparatus 100 may further include a reference light sensing element 105 disposed to sense the beam 1021 to obtain the illumination information of the light source 102 for calculating the base point of flight of time of the beam 102L.

To fully illustrate the various embodiments of the disclosure, other embodiments are provided below for explanation. It should be noted here that the following embodiments adopt the reference numbers and partial contents of the foregoing embodiments, wherein the same reference numbers are used to indicate the same or similar elements, and the description of the same technical content is omitted. For the description of the omitted parts, reference may be made to the foregoing embodiments, and the same content will not be iterated in the following embodiments.

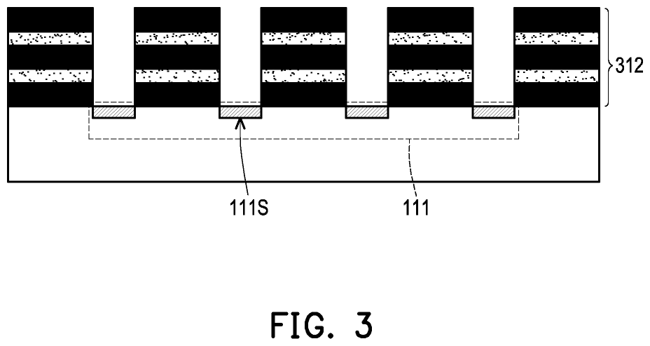

Next, referring to FIG. 3, FIG. 3 is a schematic view of a sensing device according to an embodiment of the disclosure. A sensing device 310 includes the sensing element 111 and a light-shielding structure 312. What differs the embodiment from the embodiment shown in FIG. 2A and FIG. 2B is that the light-shielding structure 312 includes multiple layer structures as shown in FIG. 3B.

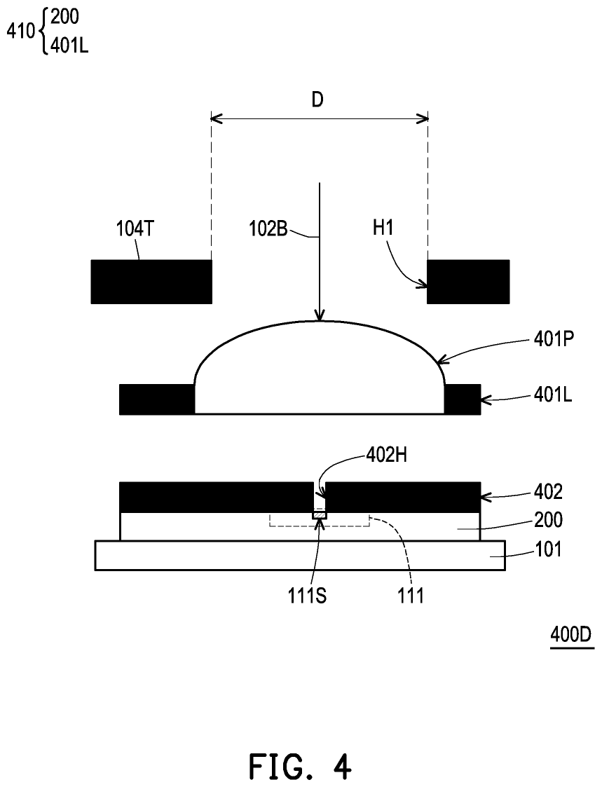

Referring to FIG. 4, FIG. 4 is a schematic view of a sensing region according to an embodiment of the disclosure. Note that to facilitate the description, the description of the light source region 100S and the encapsulation structure 104 is omitted in the embodiment. For the description of the light source region 100S and the encapsulation structure 104, refer to the description in the embodiment shown in FIG. 2A and FIG. 2B, which is not repeated herein.

What differs a sensing region 400D shown in FIG. 4 from the sensing region 100D shown in FIG. 2A and FIG. 2B is that a sensing device 410 includes the sensing element 111 and a microlens layer 401L. The sensing element 111 includes at least one of the sensing pixels 111S. The microlens layer 401L includes at least one microlens 401P. The microlens 401P is disposed on the sensing element 111, and the vertical projection of the geometric center of the microlens 401P on the substrate 101 is overlapped with the vertical projection of the geometric center of the sensing pixel 111S. The beam 102B to be sensed reflected from the object to be sensed penetrates the microlens 401P and then is incident to the sensing pixel 111S.

Note that the opening H1 is disposed corresponding to the microlens 401P, and the width of the opening H1 is larger than the field of view that the microlens 401P can receive. In such a case, even if the beam 1021 emitted by the light source 102 is reflected on the light shielding plate 104T and transmitted to the sensing region 400D, the beam 1021 may not be incident to the sensing pixel 111S, and thereby the sensing result is prevented from being interfered by the beam 1021.

In the embodiment, the distance sensing apparatus may further include at least one light-obstruction layer 402 disposed between the sensing element 111 and the microlens layer 401L, the light-obstruction layer 402 has at least one light-transmitting hole 402H, and the light-transmitting hole 402H of the light-obstruction layer 402 corresponds to the microlens 401P. In one embodiment, the vertical projection of the geometric center of the microlens 401P on the substrate 101 is overlapped with the vertical projection of the geometric center of the sensing pixel 111S and the vertical projection of the geometric center of the light-transmitting hole 402H.

In summary, the distance sensing apparatus provided by the embodiments of the disclosure includes a light-shielding structure or a microlens. The light-shielding structure or the microlens is used to limit the incident angle of a beam to be sensed which is transmitted to a sensing element, and the width of an opening of an encapsulation structure in the sensing region is further determined according to the size of the light-shielding structure or the optical characteristics of the microlens to prevent the beam emitted by the light source from being transmitted inside the encapsulation structure and affecting the sensing accuracy. With the distance sensing apparatus provided by the embodiments of the disclosure, the sensing accuracy is prevented from being affected by the opening of the encapsulation structure in the sensing region without configuring a blocking wall in the encapsulation structure.

What is claimed is:

1. A distance sensing apparatus comprising:
a substrate;
a light source disposed in a light source region on the substrate and configured to emit a beam and irradiate an object to be sensed;
a sensing device disposed in a sensing region on the substrate and comprising:
a sensing element; and
a light shielding structure disposed on the sensing element; and
an encapsulation structure, wherein the light source and the sensing device are disposed in the encapsulation structure, the encapsulation structure has a first opening corresponding to the sensing region, the light-shielding structure is disposed between the sensing element and the first opening, and the sensing element receives a beam to be sensed reflected from the object to be sensed through the first opening and at least one light-transmitting hole of the light-shielding structure,
wherein the light source region is connected to the sensing region in the encapsulation structure.

2. A distance sensing apparatus according to claim 1, wherein a width of the first opening is greater than 2H×w/h−w, H is a distance between the first opening and the sensing element in a first direction, h is a distance between a top surface of the light-shielding structure away from the sensing element and the sensing element in the first direction, w is a maximum width of the at least one light-transmitting hole in a second direction, the first direction is parallel to a normal direction of the substrate, and the second direction is perpendicular to the first direction.

3. The distance sensing apparatus according to claim 2, wherein the width of the first opening is greater than 2H×w/h.

4. The distance sensing apparatus according to claim 1, wherein the light-shielding structure comprises a plurality of layer structures.

5. The distance sensing apparatus according to claim 1, wherein the encapsulation structure has a second opening corresponding to the light source region and a light shielding plate between the second opening and the first opening.

6. The distance sensing apparatus according to claim 5, further comprising a reference light sensing element for sensing an internal beam reflected from the light shielding plate.

7. The distance sensing apparatus according to claim 1, wherein the light-shielding structure further comprises a light blocking wall disposed between the at least one light-transmitting hole and the light source.

8. The distance sensing apparatus according to claim 7, wherein the at least one light-transmitting hole corresponds to at least one sensing pixel of the sensing element.

9. The distance sensing apparatus according to claim 1, wherein a number of the at least one light-transmitting hole is plural.

10. A distance sensing apparatus, comprising:
a substrate;
a light source disposed in a light source region on the substrate and configured to emit a beam and irradiate an object to be sensed;
a sensing device disposed in a sensing region on the substrate and comprising:
a sensing element comprising at least one sensing pixel; and
a microlens layer comprising at least one microlens, wherein the at least one microlens is disposed on the sensing element, and a vertical projection of a geometric center of the at least one microlens on the substrate is overlapped with a vertical projection of a geometrical center of the at least one sensing pixel on the substrate, wherein a beam to be sensed reflected from the object to be sensed penetrates the at least one microlens and then is incident to the at least one sensing pixel; and
an encapsulation structure, wherein the light source and the sensing device are disposed in the encapsulation structure, the encapsulation structure has a first opening corresponding to the sensing region, the first opening is disposed corresponding to the at least one microlens, and a width of the first opening is greater than a field of view of the at least one microlens,
wherein the light source region is connected to the sensing region in the encapsulation structure.

11. The distance sensing apparatus according to claim 10, wherein the encapsulation structure has a second opening corresponding to the light source region and a light shielding plate between the second opening and the first opening.

12. The distance sensing apparatus according to claim 11, further comprising a reference light sensing element for sensing an internal beam reflected from the light shielding plate.

13. The distance sensing apparatus according to claim 10, further comprising at least one light-blocking layer disposed between the sensing element and the microlens layer, wherein the at least one light-blocking layer has at least one light-transmitting hole, and the at least one light-transmitting hole of the at least one light-blocking layer corresponds to the at least one microlens.

14. The distance sensing apparatus according to claim 13, wherein the vertical projection of the geometric center of the at least one microlens on the substrate is overlapped with the vertical projection of the geometric center of the at least one sensing pixel on the substrate and a vertical projection of a geometric center of the at least one light-transmitting hole on the substrate.
